(19) United States
(12) Patent Application Publication
(10) Pub. No.: US 2016/0020070 A1
(43) Pub. Date: Jan. 21, 2016

(54) PLASMA GENERATING APPARATUS USING DUAL PLASMA SOURCE AND SUBSTRATE TREATING APPARATUS INCLUDING THE SAME

(71) Applicant: PSK INC., Gyeonggi-do (KR)

(72) Inventors: Hyun Jun KIM, Hwaseong-si (KR); Chulwon JOO, Hwaseong-si (KR); Kyung Min LEE, Hwaseong-si (KR)

(73) Assignee: PSK INC.

(21) Appl. No.: 14/467,522

(22) Filed: Aug. 25, 2014

(30) Foreign Application Priority Data
Jul. 16, 2014 (KR) 10-2014-0089767

(51) Int. Cl. H01J 37/32

(52) U.S. Cl. CPC H01J 37/3211; H01J 37/3244; H01J 37/3266; H01J 37/32183

(57) ABSTRACT

Provided is a plasma generating apparatus using a dual plasma source and a substrate treating apparatus including the same. A plasma generating apparatus may include: an RF power source supplying an RF signal; a plasma chamber providing a space for generating plasma; a first plasma source disposed on a portion of the plasma chamber to generate plasma; and a second plasma source disposed on another portion of the plasma chamber to generate plasma wherein the second source comprises a plurality of gas supply loops disposed along a circumference of the plasma chamber and supplied with a process gas therein to supply the process gas to the plasma chamber; and a plurality of electromagnetic field applicators coupled to the gas supply loop and receiving the RF signal to generate plasma from the process gas.

### CROSS-REFERENCE TO RELATED APPLICATIONS

This U.S. non-provisional patent application claims priority under 35 U.S.C. §119 of Korean Patent Application No. 10-2014-0089767, on Jul. 16, 2014, the entire contents of which are hereby incorporated by reference.

### BACKGROUND OF THE INVENTION

The present invention disclosed herein relates to a plasma generating apparatus using a dual plasma source and a substrate treating apparatus including the same.

A process for fabricating a semiconductor, a display, a solar cell or the like uses a process for treating a substrate using plasma. For example, an etching device, an ashing device, a cleaning device or the like includes a plasma source for generating plasma, and a substrate may be etched, ashed, and cleaned by the plasma.

Among such plasma sources, an inductive coupling plasma (ICP) type plasma sources applies a time-variable current to a coil installed in a chamber to induce an electromagnetic filed within the chamber, and uses the induced electromagnetic field to excite a gas supplied to the chamber to a plasma state. However, the ICP type plasma source has a disadvantage that since density of plasma generated in a center region of the chamber is higher than that generated in an edge region, a density profile of the plasma distributed along a diameter of the chamber is nonuniform.

In addition, with the introduction of a process for treating a large area substrate, a decrease in process yield is emerged as a major issue due to nonuniformity of the density of plasma. Therefore, to increase a yield of a plasma process, it is required to uniformly generate plasma all over the chamber.

### SUMMARY OF THE INVENTION

The present invention provides a plasma generating apparatus capable of uniformly generating plasma in a chamber, and to a substrate treating apparatus including the same.

The present invention also provides a plasma generating apparatus capable of controlling a density profile of plasma generated in a chamber, and to a substrate treating apparatus including the same.

Embodiments of the present invention provide plasma generating apparatuses including: an RF power source supplying RF signal; a plasma chamber; a first plasma source disposed on a portion of the plasma chamber; and a second plasma source disposed on another portion of the plasma chamber, wherein the second plasma source includes a plurality of gas supply loops disposed along a periphery of the plasma chamber and supplied with a process gas therein to supply the process gas to the plasma chamber; and a plurality of electromagnetic field applicators, each of the plurality of electromagnetic field applicators coupled to respective gas supply loop and receiving the RF signal to generate plasma from the process gas.

In some embodiments, each of the electromagnetic field applicators may include: a core formed of a magnetic substance and enclosing respective gas supply loop; and a coil wound around the core.

In other embodiments, the core may include: a first core enclosing a first portion of the respective gas supply loop to form a first closed loop; and a second core enclosing a second portion of the respective gas supply loop to form a second closed loop.

In still other embodiments, the first core may include: a first sub core forming a first half portion of the first closed loop; and a second sub core forming a second half portion of the closed loop, and the second core may include: a third sub core forming a first half portion of the second closed loop; and a fourth sub core forming a second half portion of the closed loop.

In even other embodiments, the plurality of electromagnetic field applicators may be connected to each other in series.

In yet other embodiments, the plurality of electromagnetic field applicators may include a first applicator group and a second applicator group connected to each other in parallel.

In further embodiments, the plurality of electromagnetic field applicators may be configured such that the turn number of the coil wound around the core increases as going from an input terminal to a ground terminal.

In still further embodiments, the plurality of electromagnetic field applicators may be configured such that a distance between the first sub core and the second sub core, and a distance between the third sub core and the fourth sub core decrease as going from an input terminal to a ground terminal.

In even further embodiments, an insulator may be inserted between the first sub core and the second sub core and between the third core and the fourth core

In yet further embodiments, the plurality of electromagnetic field applicators may include eight electromagnetic field applicators, wherein four of the electromagnetic field applicators are connected to each other in series to form a first applicator group, remaining four of the electromagnetic field applicators are connected to each other in series to form a second applicator group, and the first applicator group and the second applicator group are connected to each other in parallel, and wherein an impedance ratio of the four electromagnetic field applicators forming the first applicator is 1:1.5:4:8 and an impedance ratio of the four electromagnetic field applicators forming the second applicator is 1:1.5:4:8.

In much further embodiments, the coil may include: a first coil wound around a portion of the core; and a second coil wound around another portion of the core, wherein the first coil and the second coil are inductively coupled to each other.

In some embodiments, the first coil and the second coil may have the same turn number.

In other embodiments, the above plasma generating apparatus may further include a reactance element connected to a ground terminal of the second plasma source.

In still other embodiments, the above plasma generating apparatus may further include a phase adjustor disposed on each of nodes between the RF power source and the plurality of electromagnetic field applicators to adjust the phases of the RF signal in the respective nodes to the same level.

In even other embodiments, the above plasma generating apparatus may further include a reactance element connected to a ground terminal of the second plasma source; and a shunt reactance element connected to each of nodes between the plurality of electromagnetic field applicators.

In yet other embodiments, an impedance of the shunt reactance element may be half of a combined impedance of the secondary coil of the coils inductively coupled to each other and the reactance element.

In further embodiments, the first plasma source may include an antenna disposed on an upper portion of the plasma chamber to induce an electromagnetic field in the plasma chamber.

In even further embodiments, the antenna may include a planar antenna disposed on an upper plane of the plasma chamber.

In other embodiments of the present invention, substrate treating apparatuses include: a process unit including a process chamber in which a substrate is disposed; a plasma generating unit generating and supplying plasma to the process unit; and a discharging unit discharging a gas and a reaction by-product from an inside of the process unit, wherein the plasma generating unit includes: an RF power source supplying RF signal; a plasma chamber; a first plasma source disposed on a portion of the plasma chamber; and a second plasma source disposed on another portion of the plasma chamber, wherein the second plasma source includes: a plurality of gas supply loops formed along a periphery of the plasma chamber and supplied with a process gas therein to supply the process gas to the plasma chamber; and a plurality of electromagnetic field applicators, each of the plurality of electromagnetic field applicators coupled to respective gas supply loop and receiving the RF signal to generate plasma from the process gas.

In some embodiments, each of the electromagnetic field applicators may include: a core formed of a magnetic substance and enclosing respective gas supply loop; and a coil wound around the core.

In other embodiments, the core may include: a first core enclosing a first portion of the respective gas supply loop to form a first closed loop; and a second core enclosing a second portion of the respective gas supply loop to form a second closed loop.

In still other embodiments of the present invention, the first core may include: a first sub core forming a first half portion of the first closed loop; and a second sub core forming a second half portion of the closed loop, and the second core may include: a third sub core forming a first half portion of the second closed loop; and a fourth sub core forming a second half portion of the closed loop.

In even other embodiments of the present invention, the plurality of electromagnetic field applicators may include a first applicator group and a second applicator group connected to each other in parallel.

In yet other embodiments of the present invention, the plurality of electromagnetic field applicators may be configured such that the turn number of the coil wound around the core increases as going from an input terminal to a ground terminal.

In further embodiments, the plurality of electromagnetic field applicators may be configured such that a distance between the first sub core and the second sub core, and a distance between the third sub core and the fourth sub core decrease as going from an input terminal to a ground terminal.

In still further embodiments, an insulator may be inserted between the first sub core and the second sub core, and between the third sub core and the fourth sub core.

In even further embodiments, the plurality of electromagnetic field applicators may include eight electromagnetic field applicators, four of the electromagnetic field applicators may be connected to each other in series to form a first applicator group, remaining four of the electromagnetic field applicators may be connected to each other in series to form a second applicator group, and the first applicator group and the second applicator group may be connected to each other in parallel, and an impedance ratio of the four electromagnetic field applicators may form the first applicator is 1:1.5:4:8 and an impedance ratio of the four electromagnetic field applicators may form the second applicator is 1:1.5:4:8.

In yet further embodiments, the coil may include: a first coil wound around a portion of the core; and a second coil wound around another portion of the core, wherein the first coil and the second coil are inductively coupled to each other.

In much further embodiments, the first coil and the second coil may have the same turn number.

In still much further embodiments, the above substrate treating apparatus may further include a reactance element connected to a ground terminal of the second plasma source.

In even much further embodiments, the above substrate treating apparatus may further include a phase adjustor disposed on each of nodes between the RF power source and the plurality of electromagnetic field applicators to adjust the phases of the RF signal on each of nodes to the same level.

In yet much further embodiments, the above substrate treating apparatus may further include: a reactance element connected to a ground terminal of the second plasma source; and a shunt reactance element connected to each of nodes between the plurality of electromagnetic field applicators.

In some embodiments, impedance of the shunt reactance element is a half of combined impedance of the secondary coil of the coils inductively coupled to each other and the reactance element.

In other embodiments, the first plasma source may include an antenna disposed on an upper portion of the plasma chamber to induce an electromagnetic field in the plasma chamber.

In still other embodiments, the antenna may include a planar antenna disposed on an upper plane of the plasma chamber.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is an exemplary schematic view illustrating a substrate treating apparatus according to an embodiment of the present invention;

FIG. 2 is an exemplary plain view illustrating a second plasma source according to an embodiment of the present invention;

FIG. 3 is an plain view illustrating a gas supply loop according to an embodiment of the present invention;

FIG. 4 is a front view illustrating an electromagnetic field applicator according to an embodiment of the present invention;

FIG. 5 is a view illustrating an equivalent circuit of a second plasma source according to an embodiment of the present invention;

FIG. 6 is an exemplary plain view illustrating a second plasma source according to another embodiment of the present invention;

FIG. 7 is a view illustrating an equivalent circuit of a second plasma source according to the other of the present invention;

FIG. 8 is an exemplary front view illustrating an electromagnetic field applying unit according to another embodiment of the present invention;

FIG. 9 is a view illustrating equivalent circuit of a second plasma source according to another embodiment of the present invention;

FIG. 10 is a view illustrating an equivalent circuit of a second plasma source according to another embodiment of the present invention;

FIG. 11 is a view illustrating an equivalent circuit of a second plasma source according to another embodiment of the present invention;

FIG. 12 is an exemplary plain view illustrating a second plasma source according to another embodiment of the present invention;

FIG. 13 is an exemplary front view illustrating an electromagnetic field applying unit according to another embodiment of the present invention; and

FIG. 14 is a view illustrating an equivalent circuit of a second plasma source according to another embodiment of the present invention.

### DETAILED DESCRIPTION OF PREFERRED EMBODIMENTS

Advantages and features of the present invention, and implementation methods thereof will be clarified through following embodiments described with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. The present invention

Though not defined, all terms (including technical or scientific terms) used herein have the same meanings as those generally accepted by universal technologies in the related art to which the present invention pertains. The terms defined by general dictionaries may be construed as having the same meanings as those in the related art and/or the text of the present application, and will not be construed as being conceptualized or excessively formal although the terms are not clearly defined expressions herein.

In the following description, the technical terms are used only for explaining a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. As used herein, the term and/or includes any and all combinations of one or more of the associated listed items.

Hereinafter, it will be described in detail about embodiments of the present invention in conjunction with the accompanying drawings.

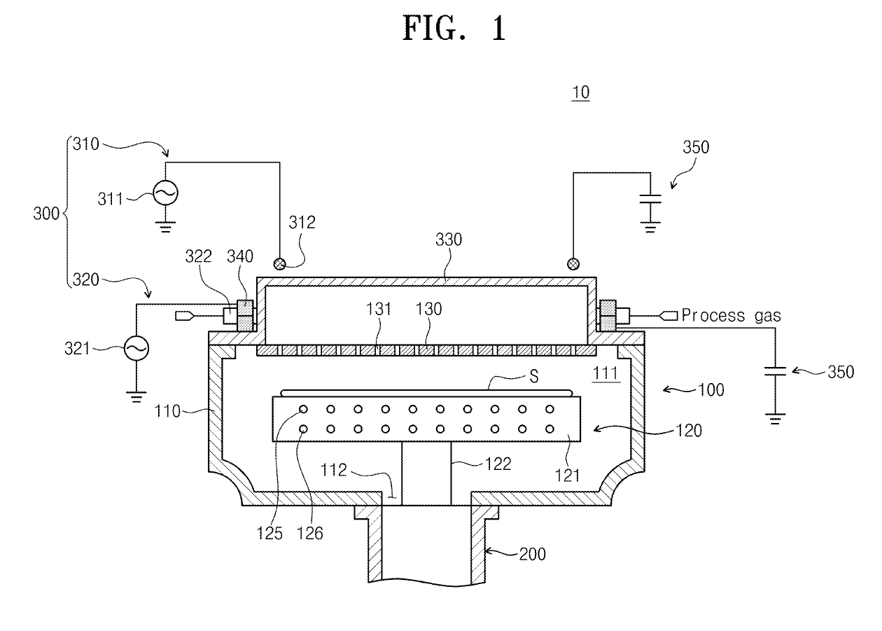

FIG. 1 is an exemplary schematic view illustrating a substrate treating apparatus 10 according to an embodiment of the present invention.

Referring to FIG. 1, the substrate treating apparatus 10 may treat, for example, etch or ash a thin film on a substrate S using plasma. The thin film to be etched or ashed may be a nitride film, as an example, a silicon nitride film. The thin film to be treated is not limited to the nitride film, but may vary depending on a process.

The substrate treating apparatus 10 may include a process unit 100, an exhaust unit 200, and a plasma generating unit 300. The process unit 100 may provide a space for placing the substrate S therein and performing an etching process or an ashing process. The exhaust unit 200 may exhaust a gas remaining in an inside of the process unit 100, a by-product generated in a substrate treating process and the like to the exterior, and maintain a pressure of the inside of the process unit 100 at a predetermined pressure. The plasma generating unit 300 may generate plasma from a process gas supplied from the exterior and supply the generated plasma to the process unit 100.

The process unit 100 may include a process chamber 110, a substrate support unit 120, and a baffle 130. The process chamber 110 may have a treating space 111 therein for performing a substrate treating process. The process chamber 110 may have an upper wall that is opened, and a side wall in which an opening (not shown) is formed. The substrate S is loaded into or unloaded from the process chamber 110 through the opening. The opening may be opened and closed by an opening/closing member, such as a door (not shown). The process chamber 110 may have a bottom surface in which an exhaust hole 112 is formed. The exhaust hole 112 may be connected to the exhaust unit 200 and provide a passage through which the gas and the by-product remaining in the inside of the process chamber 110 are exhausted to the exterior.

The substrate support unit 120 may support the substrate S. The substrate support unit 120 may include a susceptor 121 and a support shaft 122. The susceptor 121 may be disposed in an inside of the process space 111 and be provided in a disc shape. The susceptor 121 may be supported by the supporter 122. The susceptor 121 may be provided with an electrode (not shown) therein. The electrode may be connected to an external power source and generate static electricity using electric power applied thereto. The generated static electricity may fix the substrate S to the susceptor 121. The susceptor 121 may be provided with a heating member 125 therein. In an example, the heating member 125 may be a heating coil. Also, the susceptor 121 may be provided with a cooling member 126 therein. The cooling member 126 may be provided in a cooling line through which cooling water flows. The heating member 125 may heat the substrate S to a preset temperature. The cooling member 126 may forcedly cool the substrate S. The substrate S in which has been subject to a process may be cooled to room temperature or a temperature required for treating a subsequent process.

The baffle 130 may be disposed on an upper surface of the susceptor 121. The baffle 130 may be formed with holes 131. The holes 130 may be provided in through-holes penetrating the baffle 130 from top to bottom and be uniformly formed at the baffle 130.

The plasma generating unit 300 may be disposed on the process chamber 110. The plasma generating unit 300 may discharge the process gas to generate plasma, and supply the generated plasma to the process space 111. The plasma chamber 330 may include RF power sources 311 and 321, a plasma chamber 330, a first plasma source 310, and a second plasma source 320. The first plasma source 310 may be disposed on a portion of the plasma chamber 330 to generate plasma from the process gas. The second plasma source 320 may be disposed on another portion of the plasma chamber 330 to generate plasma from the process gas.

The plasma chamber 330 may be disposed on the process chamber 110 and be coupled to the process chamber 110. The plasma chamber 330 may be supplied with the process gas for generating plasma. The process gas supplied to the plasma chamber 330 may include at least one selected from, but not limited to, ammonia (NH₃), hydrogen (H₂), carbon tetrafluoride (CF₄), oxygen (O₂) and nitride (N₂).

According to an embodiment, the first plasma source 310 may be disposed on an upper surface of the plasma chamber 330 and the second plasma source 330 may be disposed on a side surface of the plasma chamber 330

The first plasma source 310 may include an antenna 312 inducing an electromagnetic field in the plasma chamber 330. In this case, the antenna 312 may receive an RF signal from the RF power source 311 to induce the electromagnetic field in the plasma chamber 330.

According to an embodiment of the present invention, the first plasma source 310 may include a planar antenna 312 disposed on the upper plane of the plasma chamber 330.

Meanwhile, the second plasma source 320 may generate plasma from the process gas by using a plurality of gas supply loops 322 and a plurality of electromagnetic field applicators 340 coupled to the plurality of gas supply loops 322.

A reactance element 350, for example, a capacitor may be connected to a ground terminal of the first plasma source 310 and a ground terminal of the second plasma source 320. The reactance element 350 may be a fixed reactance element having fixed impedance, but be a variable reactance element having variable impedance according to embodiments.

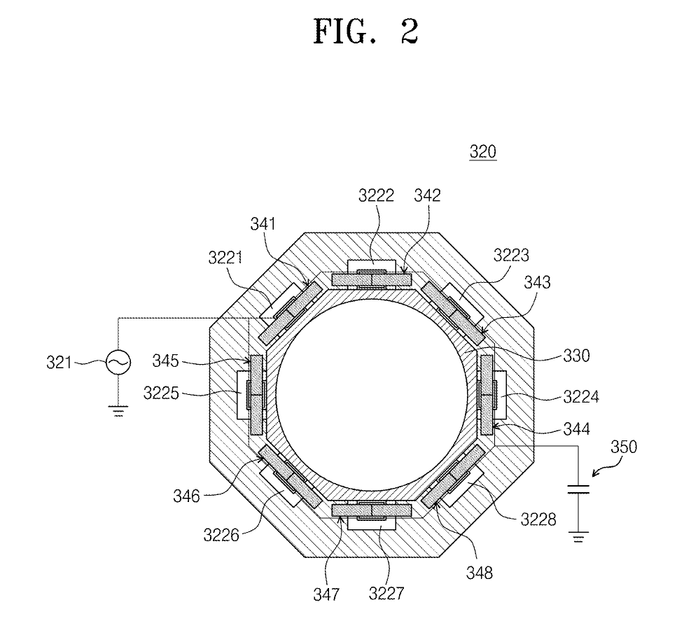

FIG. 2 is an exemplary plain view illustrating a second plasma source 320 according to an embodiment of the present invention.

As illustrated in FIG. 2, the plasma source 320 may include a plurality of gas supply loops 3221 to 3228 and a plurality of electromagnetic field applicators 341 to 348.

The plurality of gas supply loops 3221 to 3228 may be formed along a circumference of the plasma chamber 330. The plurality of electromagnetic field applicators 341 to 348 may be coupled to the plurality of gas supply loops 3221 to 3228 and receive the RF signal from the RF power source 321 to generate plasma from the process gas.

According to an embodiment, the RF power source 321 may generate the RF signal to output the generated RF signal to the plurality of electromagnetic applicators 341 to 348. The RF power source 321 may transfer high frequency electric power for generating plasma through the RF signal. According to an embodiment of the present invention, the RF power source 321 may generate and output the RF signal having a sine wave shape, but the RF signal is not limited thereto, and may rather have various wave shapes, such as a square wave, a triangle wave, a sawtooth wave, and a pulse wave.

The plasma chamber 330 may provide a space for generating plasma. According to an embodiment, the plasma chamber 330 may be formed such that an outer wall has a cross-section of a polygonal. For example, as illustrated in FIG. 2, the plasma chamber 330 may have an outer wall having a cross-section of an octagonal, but the shape of the cross-section is not limited thereto.

According to an embodiment of the present invention, the cross-section shape of the outer wall of the plasma chamber 330 may be determined depending on the number of the electromagnetic field applicator 341. For example, as illustrated in FIG. 2, when the cross-section of the outer wall of the plasma chamber 330 is the octagonal, the plurality of electromagnetic field applicators 341 to 348 may be disposed on side walls corresponding to sides of the octagonal. As described above, when the cross-section of the outer wall of the plasma chamber 330 is the polygonal, the number of a side of the polygonal may be equal to the number of the electromagnetic applicator 341. Also, as illustrated in FIG. 2, an inner wall of the plasma chamber 330 may have a cross-section of a circular shape, but the cross-section shape of the inner wall is not limited thereto.

The plurality of electromagnetic field applicators 341 to 348 may be disposed on the plasma chamber 330 and receive the RF signal from the RF power source 321 to induce an electromagnetic field. The plurality of electromagnetic filed applicators 341 to 348 may be disposed on the plasma chamber 330 through the gas supply loops 3221 to 3228 disposed on the circumference of the plasma chamber 330.

The plurality of gas supply loops 3221 to 3228 may be formed along the circumference of the plasma chamber 330. For example, as illustrated in FIG. 2, the plurality of gas supply loops 3221 to 3228 may be disposed spaced a predetermined distance apart from each other on the outer wall of the plasma chamber 330. The plasma source 320 illustrated in FIG. 2 includes eight gas supply loops 3221 to 3228, but the number of the gas supply loop 3221 may vary according to embodiments. The plurality of gas supply loops 3221 to 3228 may form a closed loop together with the outer wall of the plasma chamber 330. For example, as illustrated in FIG. 2, the plurality of gas supply loops 3221 to 328 may be formed in a shape of “ [symbol] ” or “U” and form the closed loop when disposed on the outer wall of the plasma chamber 330.

According to embodiments of the present invention, the plurality of gas supply loops 3221 to 3228 may be supplied with the process gas therein to supply the process gas to the plasma chamber 330.

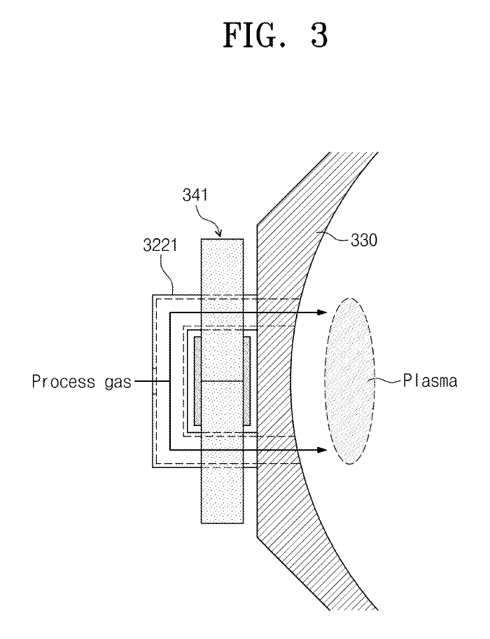

FIG. 3 is an exemplary plain view illustrating a gas supply loop 3221 according to an embodiment of the present invention.

As illustrated in FIG. 3, the process gas may be injected into the gas supply loop 3221 to move to the plasma chamber 330 through the gas supply loop 3221. For example, the gas supply loop 3221 is comprised of a hollow tube, and the process gas may move through the hollow space and be supplied to the plasma chamber 330.

Furthermore, according to embodiments of the present invention, the process gas moving in an inside of the gas supply loop 3221 may be converted into a plasma state by the electromagnetic field applicator 341 so as to be supplied to the process chamber 330. As described below, the electromagnetic field applicator 341 is comprised of a core and a coil wound around the coil and receive the RF power source 321 to induce an electric field in the gas supply loop 3221. Also, the process gas is converted into the plasma state by the induced electric field while moving through the gas supply loop 3221.

According to an embodiment, the plurality of gas supply loops 3221 to 3228 may be formed of a metal, but are limited thereto and may rather be formed of an insulator, for example, quartz or ceramic.

When the gas supply loops are formed of the insulator, the process gas may include at least one of oxygen and nitride. If the process gas, for example, ammonia or oxygen is supplied to the plurality of gas supply loops 3221 to 3228, plasma generated from the process gas may damage the plurality of gas supply loops 3221 to 3228 while passing the plurality of gas supply loops 3221 to 3228

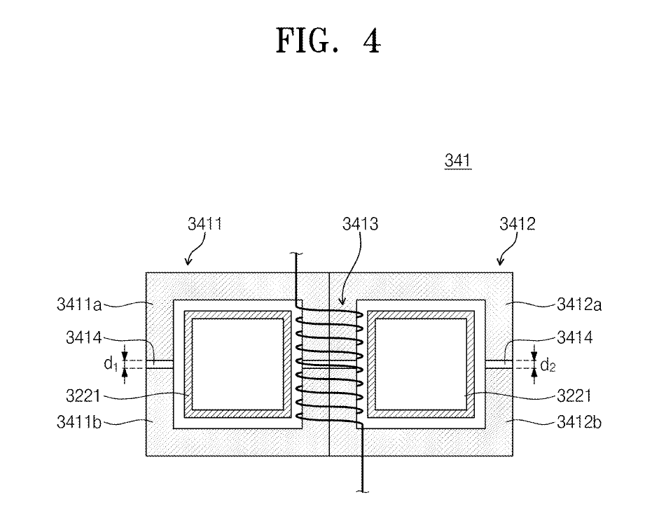

FIG. 4 is an exemplary front view illustrating an electromagnetic field applicator 341 according to an embodiment of the present invention.

The electromagnetic field applicator 341 may be formed of a magnetic substance and include cores 3411 and 3412 enclosing the gas supply loop 3221 and a coil 3413 wound around the cores 3411 and 3412. According to an embodiment, the cores 3411 and 3412 may be formed of, but is not limited to, a ferrite.

As illustrates in FIG. 4, the core may include a first core 3411 and a second core 3412. The first core 3411 may enclose a first portion of the gas supply loop 3221 to form a closed loop. The second core 3412 may enclose a second portion of the gas supply loop 3221 to form a second closed loop.

In this case, the coil 3413 may be wound around the first core 3411 and the second core 3412.

According to an embodiment, the first core 3411 and the second core 3412 may be disposed adjacent to each other. For example, as illustrated in FIG. 4, the first core 3411 and the second core 3412 may contact each other, but the first core 3411 and the second core 3412 may be spaced a predetermined distance apart from each other according to embodiments.

According to an embodiment, the first core 3411 may include a first sub core 3411a forming a half portion of the first closed loop and a second sub core 3412a forming a remaining half portion of the first closed loop. Also, the second core 3412 may include a third sub core 3412a forming a half portion of the second closed loop and a fourth sub core 3412b forming a remaining half portion of the second closed loop.

Likewise, the first core 3411 and the second core 3412 may be comprised of at least two compartments, but be formed into one according to embodiments.

As described above, the electromagnetic field applicator 341 may receive the RF signal to induce the electromagnetic field in the gas supply loop 3221. The RF signal outputted from the RF power source 321 is applied to the coil 3413 of the electromagnetic field 341 to form the electromagnetic field along the cores 3411 and 3412, and the electromagnetic field induces an electric field in the gas supply loop 3221.

According to an embodiment, the plurality of electromagnetic field applicators 341 to 348 may include a first applicator group and a second applicator group, and the first and second applicator groups may be connected to each other in series.

In detail, portions of the plurality of electromagnetic field applicators 341 to 348 may be connected to each other in series to form the first applicator group, remaining portions of the plurality of electromagnetic applicators 341 to 348 may connected to each other in series to form the second applicator group, and the first applicator group and the second applicator group may be connected to each other in parallel.

For example, as illustrated in FIG. 2, the second plasma source 320 may include eight electromagnetic field applicators 341 to 348, four electromagnetic field applicators 341 to 344 may be connected to each other in series to form the first applicator group, and remaining four electromagnetic field applicators 345 to 348 may be connected to each other in series to form the second applicator group. Also, as illustrated in FIG. 2, the first applicator group and the second group may be connected to each other in parallel.

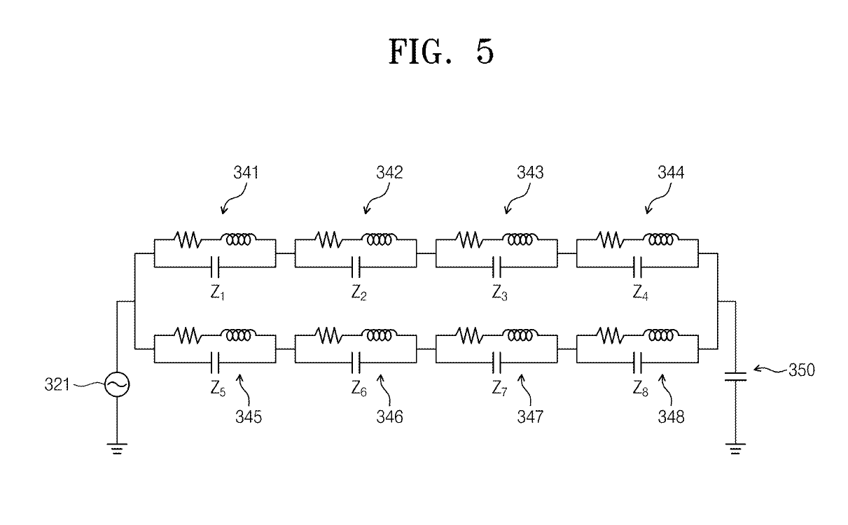

FIG. 5 is a view illustrating an equivalent circuit of a second plasma source 320 according to an embodiment of the present invention.

As illustrated in FIG. 5, each of the electromagnetic field applicator 341 to 348 may be expressed as a resistor, an inductor and a capacitor, the four electromagnetic applicators 341 to 344 forming the first applicator group may be connected to each other in series, and the four electromagnetic applicators 345 to 348 forming the second applicator group may be connected to each other in series. Also, the first applicator group and the second applicator group may be connected to each other in parallel.

According to an embodiment of the present invention, the plurality of electromagnetic field applicators 341 to 348 may be configured such that impedance increases as going from an input terminal to a ground terminal.

For example, referring to FIG. 5, among the electromagnetic applicators 341 to 344 included in the first applicator group, impedance Z1 of the first electromagnetic field applicator 341 nearest to the input terminal is lowest, impedance Z2 of the second electromagnetic field applicator 342 secondly nearest to the input terminal is second-lowest, impedance Z3 of the third electromagnetic field applicator 343 thirdly nearest to the input terminal is third-lowest, and impedance Z4 of the electromagnetic field applicator 344 fourthly nearest to the ground terminal is highest (Z1<Z2<Z3<Z4).

Also, among the electromagnetic applicators 345 to 348 included in the second applicator group, impedance Z5 of the fifth electromagnetic field applicator 345 nearest to the input terminal is lowest, impedance Z6 of the sixth electromagnetic field applicator 346 secondly nearest to the input terminal is second-lowest, impedance Z7 of the seventh electromagnetic field applicator 347 thirdly nearest to the input terminal is third-lowest, and impedance Z8 of the eight electromagnetic field applicator 348 nearest to the ground is highest (Z5<Z6<Z7<Z8).

Further, according to an embodiment of the present invention, the plurality of electromagnetic field applicators 341 to 348 corresponding to each other among the applicator groups connected to each other in parallel may have the same impedance.

For example, referring to FIG. 4, among the first applicator group and the second applicator group connected to each other in parallel, the first electromagnetic field applicator 341 and fifth electromagnetic field applicator 345 nearest to the input terminal may have the same impedance (Z1=Z5). Likewise, the second electromagnetic field applicator 342 and sixth electromagnetic field applicator 346 secondly nearest to the input terminal may have the same impedance (Z2=Z6). Also, the third electromagnetic field applicator 343 and seventh electromagnetic field applicator 347 thirdly nearest to the input terminal may have the same impedance (Z3=Z7). Finally, the fourth electromagnetic field applicator 344 and eighth electromagnetic field applicator 348 nearest to the ground terminal may have the same impedance (Z4=Z8).

According to an embodiment of the present invention, the plurality of electromagnetic field applicators 341 to 348 may be configured such that the turn number of the coil 3413 increases as going from the input terminal to the ground terminal. The turn number of the coil 3410 increases, and as a result, inductance of the coil 3413 increases, and thus the plurality of electromagnetic applicators 341 to 348 may be configured such that impedance increases as going from the input terminal to the ground terminal.

For example, referring to FIG. 2, in the case of the four electromagnetic field applicators 341 to 344 forming the first applicator group, the turn number of the coil 3413 may increase in the order of the first electromagnetic field applicator 341, the second electromagnetic field applicator 342, the third electromagnetic field applicator 343 and the fourth electromagnetic field applicator 344.

Likewise, referring to FIG. 2, in the case of the four electromagnetic field applicators 345 to 348 forming the second applicator group, the turn number of the coil 3413 may increase in the order of the fifth electromagnetic field applicator 345, the sixth electromagnetic field applicator 346, the seventh electromagnetic field applicator 347 and the eight electromagnetic field applicator 348.

Also, in comparison between the first applicator group and the second applicator group, the first electromagnetic field applicator 341 and the fifth electromagnetic field applicator 345 corresponding to each other may have the same turn number of the coil 3413, the second electromagnetic field applicator 342 and the sixth electromagnetic field applicator 346 corresponding to each other may have the same turn number of the coil 3413, the third electromagnetic field applicator 343 and the seventh electromagnetic field applicator 347 corresponding to each other may have the same turn number of the coil 3413, and the fourth electromagnetic field applicator 344 and the eighth electromagnetic field applicator 348 corresponding to each other may have the same turn number of the coil 3413.

According to another embodiment, the plurality of electromagnetic applicators 341 to 348 may be configured such that a distance d1 between the first sub core 3411A and the second sub core 3411B and a distance d2 between the third sub core 3412A and the fourth sub core 3412B are reduced as going from the input terminal to the ground terminal. As the distances d1 and d2 increases, a coupling coefficient between coils is reduced and thus inductance may decrease. Also, as inductance decreases, since impedance of the plurality of electromagnetic field applicators 341 to 348 decreases, the plurality of electromagnetic field applicator 341 to 348 may be configured such that impedance increases as going from the input terminal to the ground terminal.

For example, referring to FIG. 2, in the case of the four electromagnetic field applicator 341 to 344 forming the first applicator group, the distances d1 and d2 may be reduced in the order of the first electromagnetic field applicator 341, the second electromagnetic field applicator 342, the third electromagnetic field applicator 344 and the fourth electromagnetic field applicator 344.

Likewise, referring to FIG. 2, in the case of the four electromagnetic field applicator 345 to 348 forming the second applicator group, the distances d1 and d2 may be reduced in the order of the fifth electromagnetic field applicator 345, the sixth electromagnetic field applicator 346, the seventh electromagnetic field applicator 347 and the eighth electromagnetic field applicator 348.

Also, in comparison between the first applicator group and the second applicator group, the distances d1 and d2 of the first electromagnetic applicator 341 and the fifth electromagnetic field applicator 345 corresponding to each other may be equal, the distances d1 and d2 of the second electromagnetic applicator 342 and the sixth electromagnetic field applicator 346 corresponding to each other may be equal, the distances d1 and d2 of the third electromagnetic applicator 343 and the seventh electromagnetic field applicator 347 corresponding to each other may be equal, and the distances d1 and d2 of the fourth electromagnetic applicator 344 and the eighth electromagnetic field applicator 348 corresponding to each other may be equal.

Likewise, the plurality of electromagnetic field applicators 341 to 348 may be configured such that the turn number of the coil 3413 increases or the distances d1 and d2 between the cores are reduced as going from the input terminal to the ground terminal and thus impedance may increase, but the turn number of the coil 3413 increases and concurrently, the distances d1 and d2 between the cores are reduced as going from the input terminal to the ground terminal according to embodiments. In this case, impedance of the electromagnetic field applicator 341 may be roughly adjusted by the turn number of the coil 3413 and be finely adjusted by the distances d1 and d2 between the cores.

According to an embodiment of the present invention, the electromagnetic field applicator 341 may be configured such that an insulator 3414 is inserted between the cores.

For example, as illustrated in FIG. 4, the electromagnetic field applicator 341 may be configured such that the insulator 3414 is inserted between the first sub core 3411A and the second sub core 3411B, and between the third sub core 3412A and the fourth sub core 3412B. The insulator 3414 may be a tape formed of an insulation substance, and in this case, at least one tape may be attached between the cores in order to adjust the distances d1 and d2 between the cores.

Referring again to FIGS. 2 and 5, a second plasma source 320 according to an embodiment of the present invention may include eight electromagnetic field applicators 341 to 348, four electromagnetic field applicators 341 to 344 may be connected to each other in series to form a first applicator group and remaining four electromagnetic field applicators 345 to 348 may be connected to each other in series to form a second applicator group. The first applicator group and the second applicator group may be connected to each other in parallel.

Further, the four electromagnetic field applicators 341 to 344 forming the first applicator group may be configured such that an impedance ratio is 1:1.5:4:8, and the four electromagnetic field applicators 345 to 348 forming the second applicator group may be also configured such that an impedance ratio is 1:1.5:4:8 (Z1:Z2:Z3:Z4=Z5:Z6:Z7:Z8=1:1.5:4:8).

The second plasma source 320 illustrated in FIGS. 2 and 5 includes total eight electromagnetic field applicators 341 to 348, but the number of the electromagnetic field applicators 341 to 348 is not limited thereto, and may rather be more or less than eight.

Also, the second plasma source 320 illustrated in FIGS. 2 and 5 is configured such that total two applicator groups are connected to each other in parallel, but the number of the applicator groups connected to each other in parallel may be more than two. For example, the second plasma source 320 may include nine electromagnetic field applicators, three electromagnetic field applicators of these form one applicator group, and thus total three applicator groups may be formed. Also, the three applicator groups may be connected to each other in parallel.

The plurality of electromagnetic field applicators 341 to 348 may be connected to each other in series differently from an embodiment illustrated in FIGS. 2 and 5.

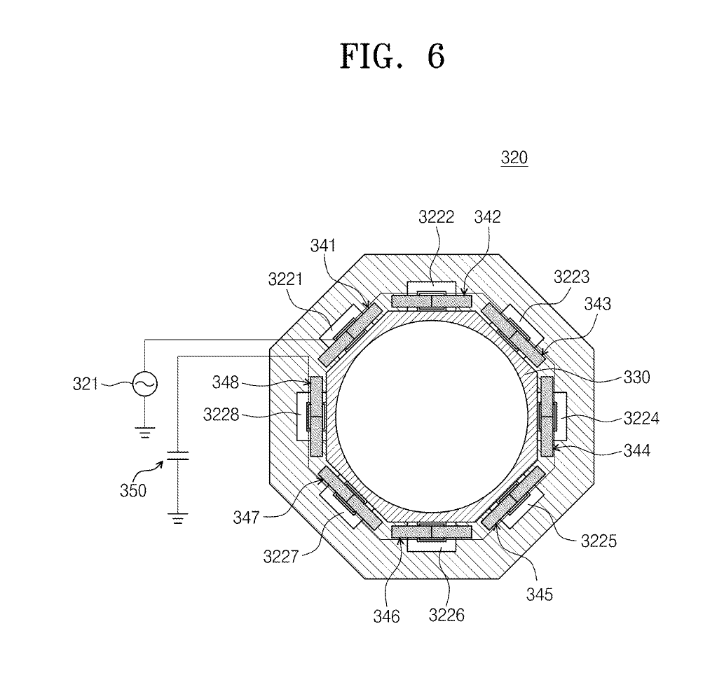

FIG. 6 is an exemplary plain view illustrating a second plasma source 320 according to another embodiment of the present invention.

Referring to FIG. 6, the second plasma source 320 may include a plurality of electromagnetic field applicators 341 to 348, but all of the plurality of electromagnetic field applicators 341 to 348 may be connected to each other in series, differently from an embodiment illustrated in FIG. 2.

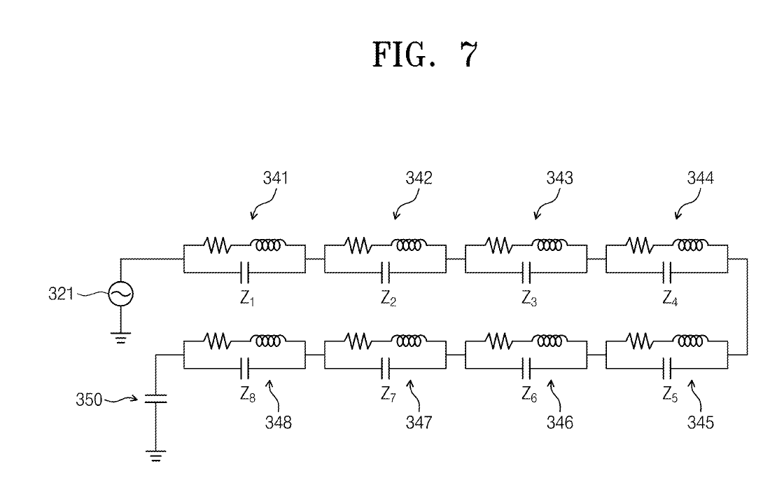

FIG. 7 is a view illustrating an equivalent circuit of a second plasma source 320 according to another embodiment of the present invention.

As illustrated in FIG. 7, all of the plurality of electromagnetic field applicators 341 to 348 may be connected to each other in series. Also, the plurality of electromagnetic field applicators 341 to 348 may be configured such that impedance increases as going from the input terminal to the ground terminal. In other words, the plurality of electromagnetic field applicators 341 to 348 may be configured such that impedance increases in the order of a first electromagnetic field applicator 341, a second electromagnetic field applicator 342, a third electromagnetic field applicator 343, a fourth electromagnetic field applicator 344, a fifth electromagnetic field applicator 345, a sixth electromagnetic field applicator 346, a seventh electromagnetic field applicator 347, and an eighth electromagnetic field applicator 348 in order adjacent to the input terminal ((Z1<Z2<Z3<Z4<Z5<Z6<Z7<Z8).

In embodiments described above, only one coil 3413 is wound around cores 3411 and 3412 forming the electromagnetic field applicator 341, but in accordance with another embodiment, a plurality of coils 3413 may be wound around the cores 3411, 3412 so as to be inductively coupled to each other.

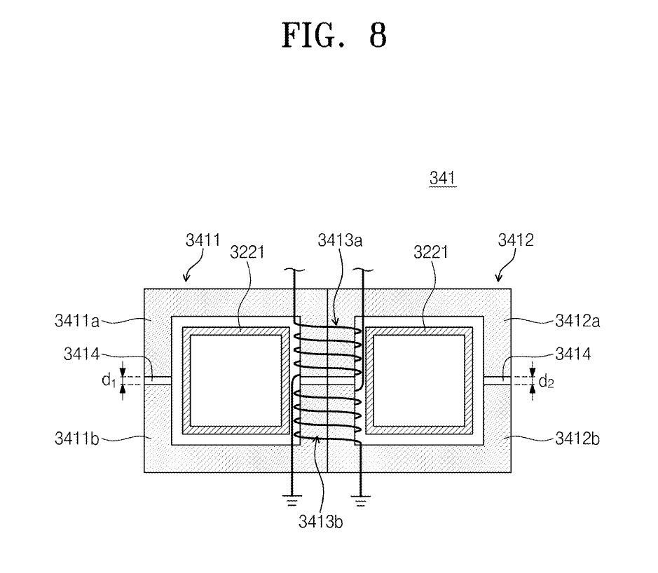

FIG. 8 is an exemplary front view illustrating an electromagnetic field applicator 341 according to another embodiment of the present invention.

Referring to FIG. 8, a coil 3413 forming the electromagnetic field applicator 341 may include a first coil 3413A wound around a portion of the cores 3411 and 3412 and a second coil 3413B wound around another portion of the cores 3411 and 3412, and the first coil 3413A and the second coil 3413B may be inductively coupled

Also, the first core 3411 and the second coil 3412 may contact each other, and the first coil 3413a and the second coil 3413b may be wound around a portion in which the first core 3411 and the second core 3412 contact each other.

Thus, the first coil 3413a and the second coil 3413b may share the cores 3412, 3412 and be separated from each other to be wound around the cores 3413 and 3412, and thus the first coil 3413a and the second coil 3413b may be inductively coupled to each other.

According to an embodiment, the coils 3413 included in each of the electromagnetic field applicators 341 to 348, for example, the first coil 3413a and the second coil 3413b may have the same turn number. In other words, a turn ratio of the two coils 3413 inductively coupled to each other may be 1 to 1.

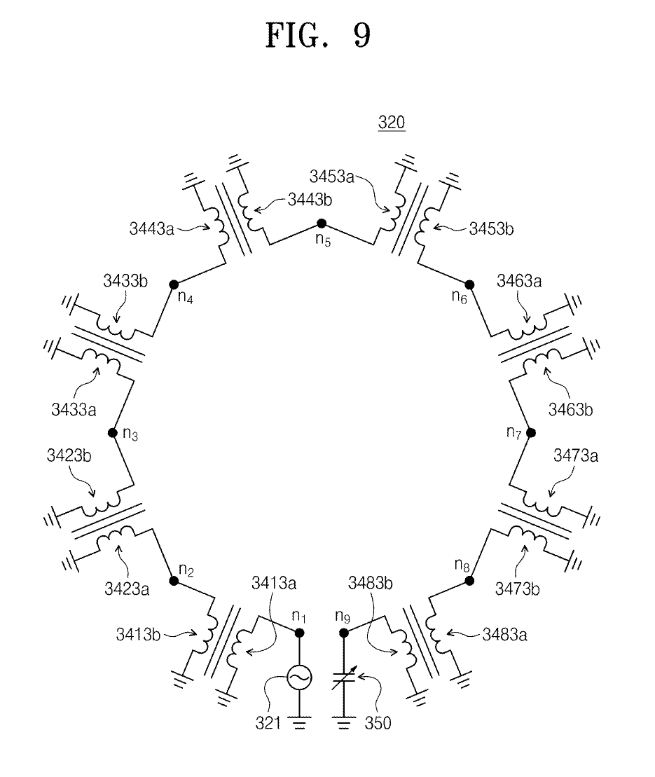

FIG. 9 is a view illustrating an equivalent circuit of a second plasma source 320 according to another embodiment of the present invention.

As illustrated in FIG. 9, since the first coil 3413A and the second coil 3413B included in each of the electromagnetic field applicators 341 to 348 may be inductively connected to each other and the turn ratio of the two coils 3413A and 3413B is 1 to 1, each of electromagnetic field applicators 341 to 348 may respond to a 1 to 1 voltage transformer.

According to an embodiment, the plurality of electromagnetic field applicators 341 to 348 may be connected to each other in series.

Regardless of whether or not the plurality of electromagnetic field applicator 341 to 348 are connected to each other in series, the coils 3413 and 3413b included in each of electromagnetic field applicators 341 to 348 are inductively coupled to each other to realize the 1 to 1 voltage transformer, and thus voltages on each of nodes n1 to n9 of the second plasma source 320 may be equal.

As a result, intensities of electromagnetic fields induced by each of electromagnetic field applicators 341 to 348 may be equal and a density of plasma generated in the plasma chamber 30 may also be uniformly dispersed on a circumference of the plasma chamber 330.

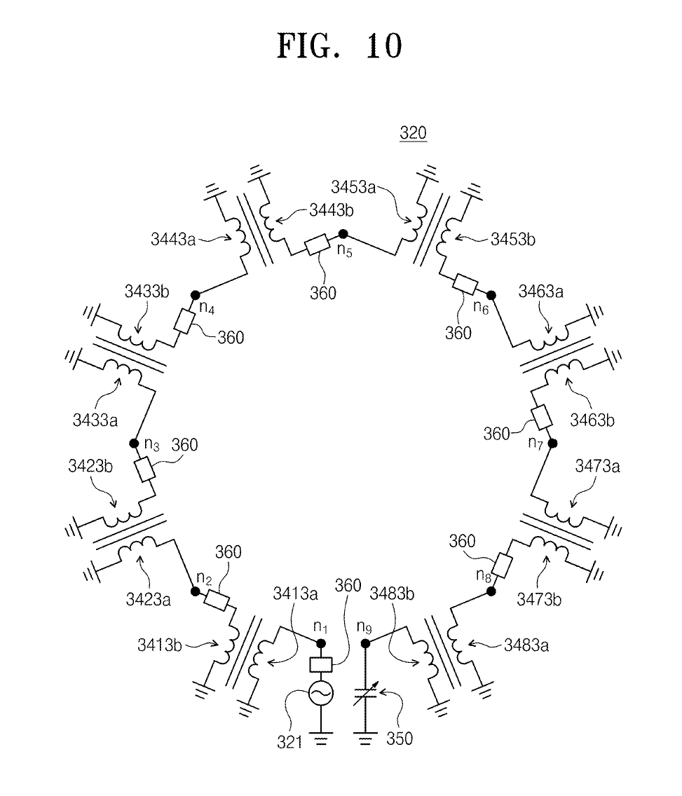

FIG. 10 is a plain view illustrating an equivalent circuit of a second plasma source 320 according to another embodiment of the present invention.

As illustrated in FIG. 10, the second plasma source 320 may further include phase adjustors 360. The phase adjustors 360 may be disposed on nodes n1 to n8 between the RF power source 321 and the plurality of electromagnetic field applicator 341 to 348 to adjust the phases of the RF signal on each of the nodes to the same level.

According to the embodiment, each voltage as well as each phase of the second plasma source 320 on each of the nodes may be adjusted to the same level.

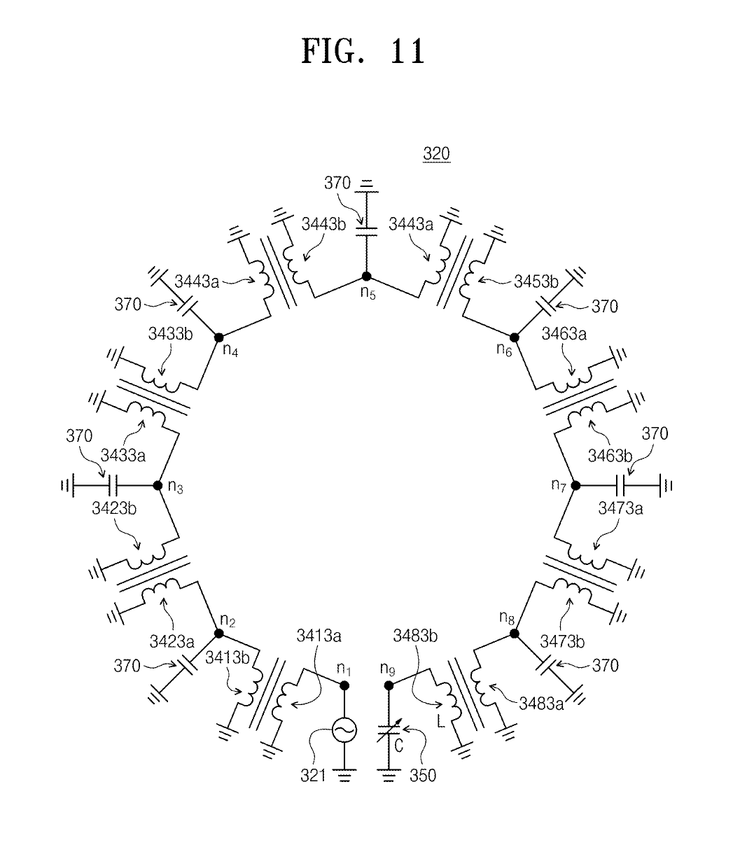

FIG. 11 is a view illustrating an equivalent circuit of a second plasma source 320 according to another embodiment of the present invention.

As illustrated in FIG. 11, the second plasma source 320 may further include a shunt impedance element 370. The shunt impedance element 370 may be connected to each of nodes n2 to n8 between the plurality of electromagnetic field applicators 341 to 348. In other words, one end of the shunt reactance element 370 may be connected to each of the nodes n1 to n8 between the plurality of electromagnetic field applicators 341 to 348 and the other end may be grounded.

According to an embodiment, the shunt reactance element 370 may be a capacitor that is a capacitive element, and impedance of the shunt reactance element may be a half of combined impedance of the secondary coil L of the coils inductively coupled to each other and the reactance element connected to the ground terminal.

According to the embodiment, the shunt reactance element 370 may make a voltage of a power supply side input terminal of the second plasma source 320 and a voltage of a ground side output terminal to the same.

According to an embodiment of the present invention, the reactance element 350 may include a variable capacitor. According to the embodiment, the second plasma source 320 may adjust capacitance of the variable capacitor to control a voltage drop in each of the electromagnetic field applicators 341 to 348.

As an example, when impedance increases by decreasing capacitance of the variable capacitor, the voltage drop increases, and as a result, a voltage drop in each of the electromagnetic field applicators 341 to 348 relatively decreases.

As another example, when impedance decreases by increasing capacitance of the variable capacitor, the voltage drop decreases, and as a result, the voltage drop in each of the electromagnetic field applicators 341 to 348 relatively increases.

Therefore, the plasma generating unit 300 may adjust the capacitance of the variable capacitor to control the voltage drop in each of the electromagnetic field applicator 341 to 348 in order to obtain a desired plasma density depending on a substrate treating process or an environment in the plasma chamber 330.

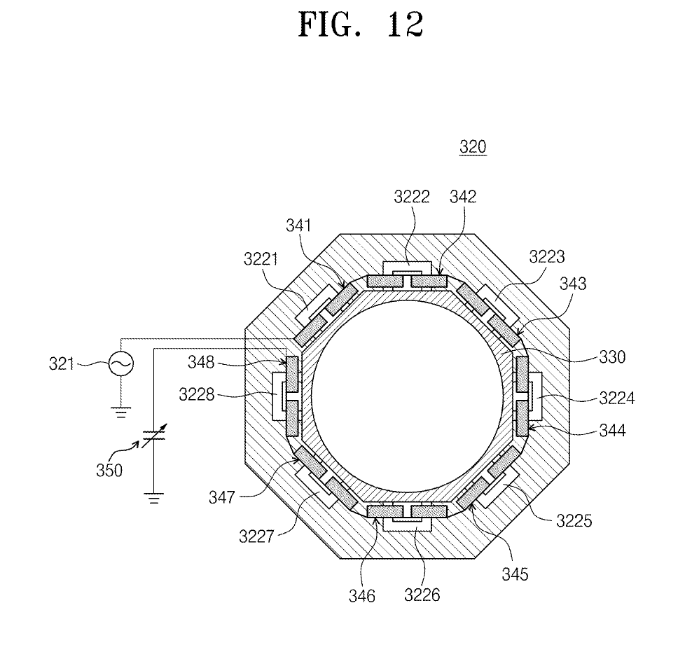

FIG. 12 is an exemplary plain view illustrating a second plasma source 320 according to another embodiment of the present invention.

An embodiment illustrated in FIG. 12 is configured such that first and second cores 3411 and 3412 are spaced apart from each other, and a first coil is wound around a portion of each of coils 3411 and 3412, and a second coil is wound around another portion of each of coils 3411 and 3412, differently from the embodiment in FIG. 8 configured such that the first and second cores 3411 and 3412 included in each of the electromagnetic field applicators 341 to 348 contact each other and the first and second coils are wound around a portion in which first and second cores 3411 and 3412 contact each other.

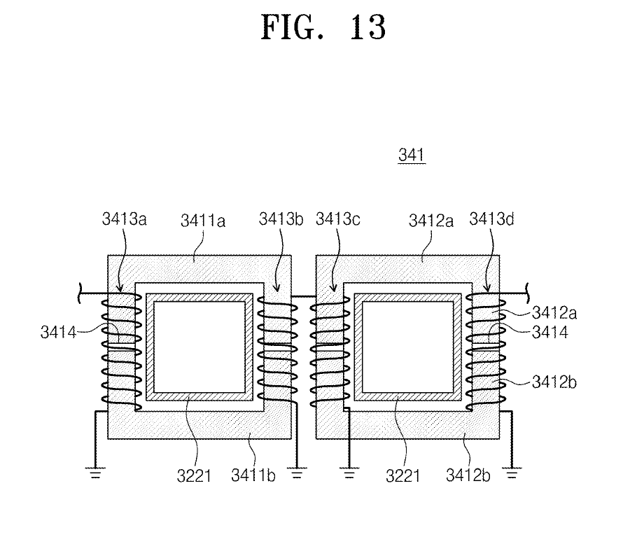

FIG. 13 is a front view illustrating an electromagnetic field applicator 341 according to another embodiment of the present invention.

As illustrated in FIG. 13, the electromagnetic field applicator 341 according to another embodiment of the present invention may be configured such that a first core 3411 and a second core 3412 are spaced apart from each other, first coils 3413a and 3413b are wound around a portion of each of cores 3411 and 3412, and second coils 3413B and 3413D are wound around another portion of each of the cores 3411 and 3412

The first and second cores 3411 and 3412 forms a separate closed loop, respectively and the first coils 3413a and 3413c and the second coils 3413b and 3413d share one core so as to be inductively coupled to each other.

The turn numbers of the coils 3413a, 3413c, 3413b and 3413d may be all the same, in this case, a turn ratio between the first coils 3413A and 3413C and the second coils 3413B and 3413D becomes 1 to 1, and thus each of cores 3411 and 3412 and the coils 3413A, 3413C, 3413B and 3413D wound around the cores 3411 and 3412 may realize a voltage transformer having a ratio of 1 to 1.

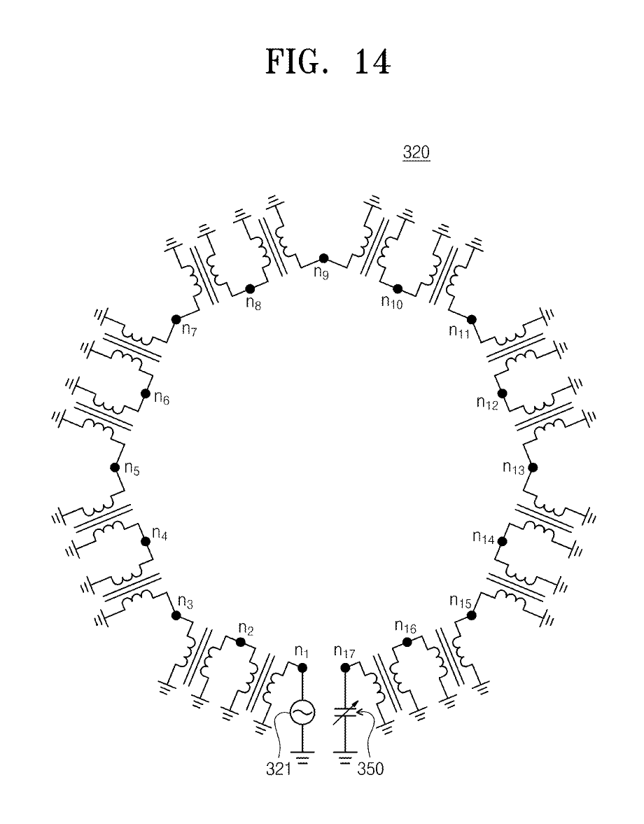

FIG. 14 is a view illustrating an equivalent circuit of a second plasma source according to another embodiment of the present invention.

As illustrated in FIG. 14, each core of the plurality of electromagnetic field applicators 341 to 348 and coils wound around the plurality of electromagnetic field applicators 341 to 348 may form a mutual inductive coupling circuit to correspond to a 1 to 1 voltage transformer.

As a result, all voltage levels on nodes n1 to n7 of the second plasma source 320 may be adjusted to be the same.

According to embodiments, a phase adjustor 360 may be provided on the nodes n1 to n6, and thus phases of the RF signal on the nodes n1 to n6 may be also be adjusted to the same level.

According to embodiments, a shunt reactance element 370 may be connected to the nodes n1 to n6 and the other end of the shunt reactance element 370 may be grounded. The shunt reactance 370 may be a capacitor, and impedance of the shunt reactance element 370 may be adjusted to a half of combined impedance of the secondary coil of the coils inductively coupled to each other and the reactance element.

Embodiments of the present invention having the first and second plasma source 310 and 321 have been described above.

According to embodiments of the present invention, the first plasma source 310 generates plasma having a density in an center region of the plasma chamber 330 higher than that an edge region of the plasma chamber 330 and the second plasma source 320 generates plasma having a density in the edge region of the plasma chamber 330 higher than that the center region of the plasma chamber 330.

As a result, the plasma unit 300 may obtain plasma having a uniform density over the plasma chamber 330 by combining plasma generated by the first plasma source 310 and plasma generated by the second plasma source 320.

Furthermore, RF electric power supplied to the first plasma source 310 and the second plasma source 320 may be adjusted to obtain plasma having the density in the brim region of the plasma chamber 330 higher than that in the center region of the plasma chamber 330, or on the contrary, to obtain plasma having the density in the center region of the plasma chamber 330 higher than that in the brim region of the plasma chamber 330

Such an adjustment of the RF electric power may be achieved by controlling output electric power of the RF power sources 311 and 312 in a predetermined proportion. According to embodiments, when the first and second plasma sources 310, 320 are supplied with electric power from one RF power source, a power distribution circuit may be provided between the RF power source and the plasma sources 310 and 320 to adjust electric power supplied to each of the plasma sources 310 and 320.

According to an embodiment of the present invention, plasma may be uniformly generated in the plasma chamber 330. Specially, plasma may be uniformly generated also in a large-scale chamber for treating a large area substrate or a density profile of plasma may be controlled generated over the chamber.

According to embodiments of the present invention, when treating the large area substrate, a process yield may be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A plasma generating apparatus comprising:
an RF power source supplying RF signal;
a plasma chamber;
a first plasma source disposed on a portion of the plasma chamber; and
a second plasma source disposed on another portion of the plasma chamber,
wherein the second plasma source comprises;
a plurality of gas supply loops disposed along a periphery of the plasma chamber and supplied with a process gas therein to supply the process gas to the plasma chamber; and
a plurality of electromagnetic field applicators, each of the plurality of electromagnetic field applicators coupled to respective gas supply loop and receiving the RF signal to generate plasma from the process gas.

2. The plasma generating apparatus of claim of claim 1, wherein each of the electromagnetic field applicators comprises:
a core formed of a magnetic substance and enclosing respective gas supply loop; and
a coil wound around the core.

3. The plasma generating apparatus of claim 2, wherein the core comprises:
a first core enclosing a first portion of the respective gas supply loop to form a first closed loop; and
a second core enclosing a second portion of the respective gas supply loop to form a second closed loop.

4. The plasma generating apparatus of claim 3, wherein the first core comprises:
a first sub core forming a first half portion of the first closed loop; and
a second sub core forming a second half portion of the closed loop, and
the second core comprises:
a third sub core forming a first half portion of the second closed loop; and
a fourth sub core forming a second half portion of the closed loop.

5. The plasma generating apparatus of claim 4, wherein the plurality of electromagnetic field applicators are configured such that a distance between the first sub core and the second sub core and a distance between the third sub core and the fourth sub core decrease as going from an input terminal to a ground terminal.

6. The plasma generating apparatus of claim 5, wherein an insulator is inserted between the first sub core and the second sub core and between the third core and the fourth core.

7. The plasma generating apparatus of claim 1, wherein the plurality of electromagnetic field applicators are connected to each other in series.

8. The plasma generating apparatus of claim 1, wherein the plurality of electromagnetic field applicators comprise first applicator group and a second applicator group connected to each other in parallel.

9. The plasma generating apparatus of claim 2, wherein the plurality of electromagnetic field applicators are configured such that the turn number of the coil wound around the core increases as going from an input terminal to a ground terminal.

10. The plasma generating apparatus of claim 1, wherein the plurality of electromagnetic field applicators comprises eight electromagnetic field applicators,
wherein four of the electromagnetic field applicators are connected to each other in series to form a first applicator group, remaining four of the electromagnetic field applicators are connected to each other in series to form a second applicator group, and the first applicator group and the second applicator group are connected to each other in parallel, and
wherein an impedance ratio of the four electromagnetic field applicators forming the first applicator is 1:1.5:4:8 and an impedance ratio of the four electromagnetic field applicators forming the second applicator is 1:1.5:4:8.

11. The plasma generating apparatus of claim 2, wherein the coil comprises:
a first coil wound around a portion of the core; and
a second coil wound around another portion of the core,
wherein the first coil and the second coil are inductively coupled to each other.

12. The plasma generating apparatus of claim 11, wherein the first coil and the second coil have the same turn number.

13. The plasma generating apparatus of claim 1, further comprising a reactance element connected to a ground terminal of the second plasma source.

14. The plasma generating apparatus of claim 1, further comprising a phase adjustor disposed on each of nodes between the RF power source and the plurality of electromagnetic field applicators to adjust each of phases of the RF signal on each of nodes to the same level.

15. The plasma generating apparatus of claim 11, further comprising: a reactance element connected to a ground terminal of the second plasma source; and
a shunt reactance element connected to each of nodes between the plurality of electromagnetic field applicators.

16. The plasma generating apparatus of claim 15, wherein impedance of the shunt reactance element is a half of combined impedance of the secondary coil of the coils inductively coupled to each other and the reactance element.

17. The plasma generating apparatus of claim 1, wherein the first plasma source comprises an antenna disposed on an upper portion of the plasma chamber to induce an electromagnetic field in the plasma chamber.

18. The plasma generating apparatus of claim 17, wherein the antenna comprises a planar antenna disposed on an upper plane of the plasma chamber.

19. A substrate treating apparatus, the apparatus comprising:
a process unit including a process chamber in which a substrate is disposed;
a plasma generating unit generating and supplying plasma to the process unit; and
a discharging unit discharging a gas and a reaction by-product from an inside of the process unit,
wherein the plasma generating unit comprises:
an RF power source supplying RF signal;
a plasma chamber;
a first plasma source disposed on a portion of the plasma chamber; and
a second plasma source disposed on another portion of the plasma chamber,
wherein the second plasma source comprises:
a plurality of gas supply loops formed along a periphery of the plasma chamber and supplied with a process gas therein to supply the process gas to plasma chamber; and
a plurality of electromagnetic field applicators, each of the plurality of electromagnetic field applicators coupled to respective gas supply loop and receiving the RF signal to generate plasma from the process gas.
